(19) United States
(12) Patent Application Publication
(10) Pub. No.: US 2009/0291233 A1
(43) Pub. Date: Nov. 26, 2009

(54) PROCESS FOR PRODUCING GAS BARRIER FILMS

(75) Inventors: Toshiya TAKAHASHI, Odawara-shi (JP); Tatsuya FUJINAMI, Odawara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/471,098

(22) Filed: May 22, 2009

(30) Foreign Application Priority Data
May 23, 2008 (JP) 2008-135392

(51) Int. Cl. C23C 16/30; B05D 3/00

(52) U.S. Cl. 427/569

(57) ABSTRACT

A process for producing gas barrier films comprises the steps of: applying a pressure of 50 N/m² and above to a surface of a substrate; and subsequently forming a gas barrier layer on the surface of the substrate by plasma-enhanced CVD in a pressure atmosphere of 60 Pa and above.

### BACKGROUND OF THE INVENTION

The present invention relates to a production of gas barrier films using plasma-enhanced CVD, more particularly to a process by which films of high gas barrier quality can be produced in a consistent manner using a film depositing apparatus of the roll-to-roll type.

Gas barrier films (water-vapor barrier films) are utilized not only at those sites of optical devices, display apparatuses (e.g. liquid-crystal displays and organic EL displays) as well as various other devices including semiconductor devices and thin-film solar batteries which are required to be moisture-proof, but also in packaging materials used to pack foods, clothing items, electronic components, etc.

Gas barrier films are typically composed of a film of a polymeric material (plastic film) or a metal film that has deposited on its surface a gas barrier layer made of silicon oxide, silicon nitride or other materials that exhibit gas barrier quality.

To ensure that film deposition is performed by vacuum film depositing techniques with high efficiency and productivity, films are preferably deposited in a continuous manner on an elongated substrate.

Known as an apparatus for implementing this film deposition method is a so-called roll-to-roll type machine that uses a substrate roll or a roll of elongated substrate (web of substrate) and a takeup roll around which the substrate with a deposited layer is wound.

This roll-to-roll type machine is so adapted that the elongated substrate is directed from the substrate roll to the takeup roll in a specified path through a film deposition compartment (film depositing section) where a layer is to be deposited on the substrate by a vapor-phase film deposition technique such as plasma-enhanced CVD and that a layer is deposited continuously on the substrate in the process of transport in the film deposition compartment as the substrate is unwound from the substrate roll in synchronism with the rewinding of the substrate by the takeup roll after the layer is deposited on the substrate.

For example, JP 2003-291247 A discloses a process for producing gas barrier films using a roll-to-roll type film depositing apparatus, in which a metal (oxide) layer and a carbon layer are formed on a surface of a substrate with the plasma excitation power (microwave supply power) being set at 50-350 W and the film deposition pressure at 0.1-20 Pa.

The roll-to-roll type film depositing apparatus is usually equipped with transport means such as guide rollers and a transport roller pair in order to ensure that the substrate is properly transported in a specified path.

However, if plasma-enhanced CVD is employed to produce gas barrier films by depositing a gas barrier layer with the roll-to-roll type machine, gas barrier films having the desired gas barrier quality cannot sometimes be produced in a consistent manner depending on such factors as the state in which the substrate is being transported.

### SUMMARY OF THE INVENTION

An object, therefore, of the present invention is to solve the aforementioned problem of the prior art by providing a process by which gas barrier films having the desired gas barrier quality can be produced in a consistent manner.

A process for producing gas barrier films according to the present invention comprises the steps of: applying a pressure of 50 N/m² and above to a surface of a substrate; and subsequently forming a gas barrier layer on the surface of the substrate by plasma-enhanced CVD in a pressure atmosphere of 60 Pa and above.

### BRIEF DESCRIPTION OF THE DRAWINGS

FIG. 1 shows in concept the construction of an apparatus for implementing a gas barrier film production process according to an embodiment of the present invention.

FIG. 2A illustrates how a foreign object on a surface of a substrate deforms as it is subjected to an area pressure.

FIG. 2B depicts a gas barrier layer that has been produced by a conventional method in the presence of a foreign object.

FIG. 2C depicts a gas barrier layer that has been produced by the method of the present invention in the presence of a foreign object.

FIG. 3 is a graph showing the relation between the film deposition pressure and the water-vapor transmission rate, as observed in an Example of the present invention.

### DETAILED DESCRIPTION OF THE INVENTION

On the following pages, the process of the present invention for producing gas barrier films is described in detail with reference to the preferred embodiment shown in the accompanying drawings.

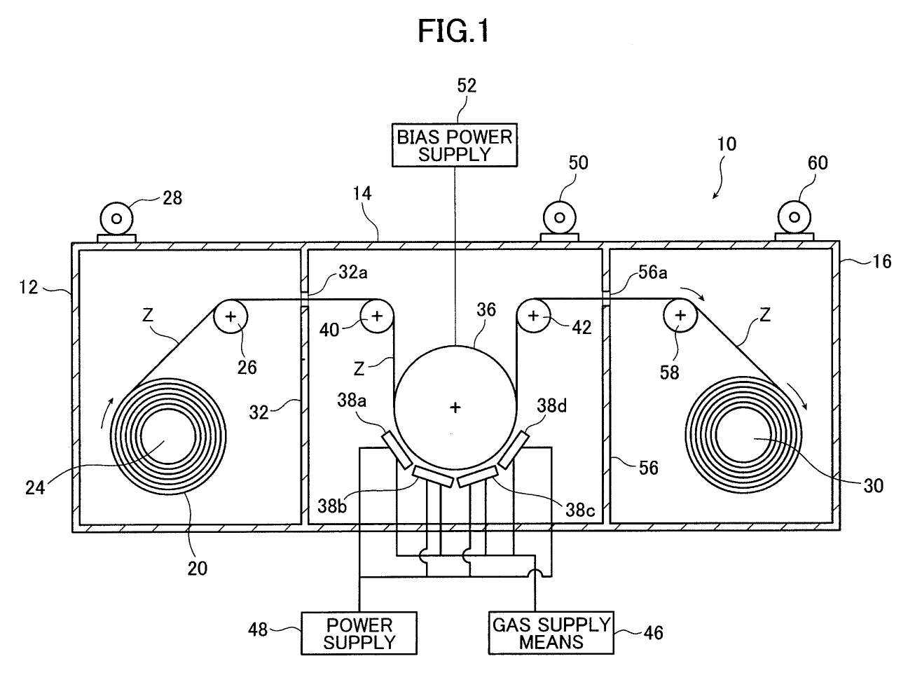

FIG. 1 shows a gas barrier film producing apparatus that is generally indicated by 10 for implementing the process of the present invention for producing gas barrier films.

The gas barrier film producing apparatus 10 is so adapted that a gas barrier layer is deposited on a surface of an elongated substrate Z (a web of film) by plasma-enhanced CVD as it is transported in a longitudinal direction, whereby a gas barrier film is produced.

With this apparatus 10, film deposition is performed by the so-called roll-to-roll approach, in which a substrate roll 20 as a roll of the elongated substrate Z is unwound to deliver the substrate Z, which is transported in the longitudinal direction as a gas barrier layer is deposited on it, and in which the substrate Z having the gas barrier layer deposited thereon is rewound in a roll form.

The apparatus 10 has a supply compartment 12, a film deposition compartment 14, and a takeup compartment 16.

Note that in addition to the members shown in FIG. 1, the apparatus 10 may include a variety of members (transport means) for transporting the substrate Z in a specified path, as exemplified by a transport roller pair and guide members that regulate the position of the substrate Z in the direction of its width.

The supply compartment 12 has a rotating shaft 24, a guide roller 26, and an evacuating means 28.

The substrate roll 20 as a roll of the elongated substrate Z is mounted on the rotating shaft 24 in the supply compartment 12.

After the substrate roll 20 is mounted on the rotating shaft 24, the substrate Z is guided in a specified transport path that extends from the supply compartment 12 through the film deposition compartment 14 to a takeup shaft 30 in the takeup compartment 16.

In the apparatus 10, delivery of the substrate Z from the substrate roll 20 is performed in synchronism with rewinding of the substrate Z (i.e., gas barrier film) by the takeup shaft 30 in the takeup compartment 16, whereupon the elongated substrate Z is transported longitudinally in the specified transport path while a gas barrier layer is continuously deposited on the substrate Z by plasma-enhanced CVD in the film deposition compartment 14.

In the present invention, the substrate Z on which a gas barrier layer is to be deposited is not particularly limited and various resin films (polymeric films or plastic films) such as PET films, various metal sheets such as aluminum sheets, and all other kinds of substrates (base films) that are utilized in known gas barrier films can be adopted as long as they enable gas barrier layers to be deposited by plasma-enhanced CVD.

If desired, the substrate Z may be such that a variety of layers (e.g., a protective layer, an adhesive layer, a light reflecting layer, a light shield layer, a planarizing layer, a buffer layer, and a stress relaxing layer) that are made of inorganic or organic matter to exhibit various functions are also formed on a surface of a resin film, a metal sheet or the like that serve as the substrate.

In the supply compartment 12, the rotating shaft 24 is turned clockwise in FIG. 1 by means of a drive source (not shown), whereupon the substrate Z is unwound from the substrate roll 20, guided by the guide roller 26 to travel in a specified path, and sent into the film deposition compartment 14 through a slit 32a formed in a partition 32.

In the illustrated case, the guide roller 26 contacts a surface of the substrate Z (the side where a gas barrier layer is to be deposited) at a pressure of 50 N/m² or above. In other words, the substrate Z is given such a tension that it will receive a pressure of no less than 50 N/m² as exerted by the guide roller 26.

In the illustrated apparatus 10, the evacuating means 28 evacuates the supply compartment 12 so that its interior has the same degree of vacuum (pressure) as the film deposition compartment 14 during film deposition to thereby prevent the pressure in the supply compartment 12 from affecting the degree of vacuum in the film deposition compartment 14 (and hence the deposition of a gas barrier layer).

The evacuating means 28 is not particularly limited and one may utilize vacuum pumps such as a turbo pump, a mechanical booster pump and a rotary pump, as well as a variety of known evacuating means that are employed in vacuum film depositing apparatuses utilizing an auxiliary means such as a cryogenic coil, a means for adjusting the ultimate degree of vacuum or the volume to be evacuated, and other means. The same is true for the other evacuating means to be described later.

In the apparatus 10 shown in FIG. 1, each of the supply compartment 12, the film deposition compartment 14 and the takeup compartment 16 is equipped with an evacuating means, but no evacuating means need be provided for the supply compartment 12 and the takeup compartment 16 where there is no inherent need to perform evacuation. In this case, however, in order to reduce the effect that the pressures in the supply compartment 12 and the takeup compartment 16 might have on the degree of vacuum in the film deposition compartment 14, the slit 32a and other sites through which the substrate Z passes are preferably made as small as possible, or alternatively, the pressure in a sub-chamber optionally provided between the supply compartment 12 and the film deposition compartment 14 and between the film deposition compartment 14 and the takeup compartment 16 is preferably reduced.

In the illustrated apparatus 10 where each of the supply compartment 12, the film deposition compartment 14 and the takeup compartment 16 is equipped with an evacuating means, the slit 32a and other sites through which the substrate Z passes are also preferably made as small as possible.

As noted above, the substrate Z is guided by the guide roller 26 to be transported into the film deposition compartment 14.

The film deposition compartment 14 is a site where a gas barrier layer is deposited (formed) on a surface of the substrate Z by CCP (capacity coupled plasma) enhanced CVD.

It should be noted here that the plasma-enhanced CVD to be performed in the present invention is by no means limited to CCP-enhanced CVD and that all of the known plasma-enhanced CVD techniques including ICP (inductively coupled plasma) enhanced DVD can be utilized as long as they are capable of depositing gas barrier layers under the condition that the film deposition pressure be 60 Pa or above.

However, in the present invention, gas barrier layers are deposited by plasma-enhanced CVD with the film deposition pressure set at 60 Pa or above, preferably at 100 Pa or above; hence, CCP-enhanced CVD which is capable of performing satisfactory film deposition at those film deposition pressures is more advantageous.

In the illustrated case, the film deposition compartment 14 has a drum 36, showerhead electrodes 38a, 38b, 38c and 38d, guide rollers 40 and 42, a gas supply means 46, a RF power supply 48, and an evacuating means 50.

The drum 36 in the film deposition compartment 14 is a cylindrical member that turns counterclockwise about its centerline as seen in FIG. 1. The substrate Z guided by the guide roller 40 into a specified path is wrapped on the periphery of the drum 36 to cover a specified region and transported in a longitudinal direction as it is held in specified positions which are in a face-to-face relation with the showerhead electrodes 38a to 38d. The drum 36 preferably has a temperature adjusting means that enables the temperature of the substrate Z to be adjusted while it is in the process of film deposition.

It should be noted here that like the previously described guide roller 26, the guide roller 40 which guides the substrate Z towards the drum 36 and allows it to be wrapped around the drum 36 contacts a surface of the substrate Z at a pressure of 50 N/m² and above.

The drum 36 also works as a counter electrode in CCP-enhanced CVD (i.e., it combines with each showerhead electrode to form an electrode pair) and in a preferred embodiment, it is connected to a bias power supply 52.

Note this is not the sole case of the present invention and the drum 36 serving as a counter electrode may be grounded. Alternatively, the drum 36 may be so adapted that mode selection can be made between connection to the bias power supply 52 and grounding.

The showerhead electrodes 38a to 38d are known types that are utilized in film deposition by CCP-enhanced CVD.

In the illustrated case, the showerhead electrodes 38a to 38d each assume a hollow rectangular parallelepiped form as a typical shape and are each positioned in such a way that one major surface is in a face-to-face relation with the periphery of the drum 36 and that a line dropped perpendicular from the center of that major surface coincides with the normal line to the drum 36. The side of each showerhead electrode that faces the drum 36 has a number of through-holes formed across its surface.

In the illustrated case, four showerhead electrodes (means of film deposition by CCP-enhanced CVD) are provided but this is not the sole case of the present invention and the number of showerhead electrodes may be one, two or three, or it may even be greater than four.

The present invention is not limited to the case of performing film deposition using showerhead electrodes, either, and it may employ ordinary electrodes in plate form and gas supply nozzles.

The gas supply means 46 is a known type that is used with vacuum film deposition apparatuses such as a plasma-enhanced CVD apparatus and it supplies reaction gases into each of the showerhead electrodes 38a to 38d.

As already mentioned, the side of each showerhead electrode that faces the drum 36 has a number of through-holes formed in its surface. Hence, the reaction gases supplied to the showerhead electrodes 38a to 38d are introduced into the space between each showerhead electrode and the drum 36 via those through-holes.

Note that the gas supply means 46 may be of such a design that it supplies the same amounts of reaction gases to all showerhead electrodes 38a to 38d or, alternatively, of such a design that they individually have a means of adjusting the gas flow rates (which may be mounted on a piping system).

In the illustrated case, the showerhead electrodes 38a to 38d collectively have the single gas supply means 46; if desired, each of the showerhead electrodes 38a to 38d may have a gas supply means or, in yet another case, a gas supply means may be provided for each of the reaction gases to be supplied.

The RF power supply 48 is one that supplies plasma excitation power to the showerhead electrodes 38a to 38d.

The RF power supply 48 may also be of any known types that are utilized in a variety of plasma-enhanced CVD apparatuses.

The substrate Z supplied from the supply compartment 12 and guided by the guide roller 40 is wrapped around the periphery of the drum 36 to cover the specified region and transported in the specified transport path as it is supported and guided by the drum 36.

The interior of the film deposition compartment 14 is evacuated by the evacuating means 50 to a specified degree of vacuum. In addition, the showerhead electrodes 38a to 38d are supplied with reaction gases from the gas supply means 46 such that they are introduced into the space between each showerhead electrode and the substrate Z (or the drum 36 that carries it). Further in addition, the showerhead electrodes 38a to 38d are supplied with power from the RF power supply 48 whereas the drum 36 is supplied with bias power from the bias power supply 52.

As a result, plasma is excited between each of the electrodes 38a to 38d and the drum 36, whereupon the reaction gases are ionized and a gas barrier layer is deposited by CCP-enhanced CVD on a surface of the substrate Z as it is supported and transported by the drum 36.

The substrate Z on which the gas barrier layer has been deposited (i.e., a gas barrier film) is then transported from the drum 36 to the guide roller 42, which guides the gas barrier film to be transported into the takeup compartment 16 via a slit 56a formed in a partition 56 that separates the film deposition compartment 14 and the takeup compartment 16.

It should be remembered here that in the present invention, the pressure for film deposition by plasma-enhanced CVD in the film deposition compartment 14 is at least 60 Pa.

It should also be remembered that in the illustrated apparatus 10, the guide rollers 26 and 40 which contact the surface of the substrate Z (on the side where the gas barrier layer is to be deposited) before deposition of the gas barrier layer exert a pressure of 50 N/m² and more on that surface of the substrate Z (in other words, the guide rollers 26 and 40 press the substrate's surface at a pressure of 50 N/m² and more.)

Adopting the above-described structural design, the present invention ensures that gas barrier films having the desired gas barrier quality can be produced consistently by depositing a gas barrier layer through plasma-enhanced CVD using a roll-to-roll type machine.

As already mentioned in connection with the prior art, if plasma-enhanced CVD is employed to produce gas barrier films by depositing a gas barrier layer with the roll-to-roll type machine, gas barrier films having the desired gas barrier quality cannot sometimes be produced depending on the state in which the substrate Z is being transported.

The present inventors conducted intensive studies in order to locate the cause of that failure; as a result, they found that when the surface of the substrate Z was depressed before deposition of a gas barrier layer on the substrate Z, foreign objects adhering to the substrate's surface were also depressed so that they assumed an inverse tapered shape, and the gas barrier layer deposited over these inverse tapers was inappropriate in one way or another.

As already mentioned, the substrate Z is transported from the supply compartment 12 into the film deposition compartment 14, where a gas barrier layer is deposited on its surface. Although the pressure in the supply compartment 12 and the film deposition compartment 14 has been reduced to a specified degree of vacuum, it is impossible to ensure that all foreign objects such as grit and dust are thoroughly removed from the interiors of those compartments (i.e., vacuum chambers). What is more, the film deposition compartment 14 also contains the particulate matter that was generated during the previous cycle of film deposition and the particulate that is being generated by the current cycle of film deposition.

When the apparatus for vacuum film deposition is operated, those foreign objects cannot be thoroughly prevented from suspending in the atmosphere in the compartments and adhering to the surface of the substrate Z. As a further problem, there may be some foreign objects that have already adhered to the surface of the substrate Z while it was in the form of the substrate roll 20.

During the operation of the roll-to-roll type machine with which the substrate Z is unwound from the substrate roll 20 and passed into a specified path so that a gas barrier layer is deposited on the substrate Z being transported, it is required that the substrate Z be transported correctly in the specified path. To ensure that the substrate Z is transported correctly in the specified path, the guide rollers, transport roller pair and other members that contact the surface of the substrate Z (i.e., the side where the gas barrier layer is to be deposited) are essential and it would be difficult to eliminate them without compromising the intended object.

To perform the correct transport of the substrate Z in a consistent manner, it need be transported with a certain amount of tension being applied. This causes the surface of the substrate Z to be depressed by the guide rollers. In the case of the transport roller pair, the substrate Z needs to be held by a certain amount of nip force in order to secure its correct transport and this nip force also works to depress the surface of the substrate Z.

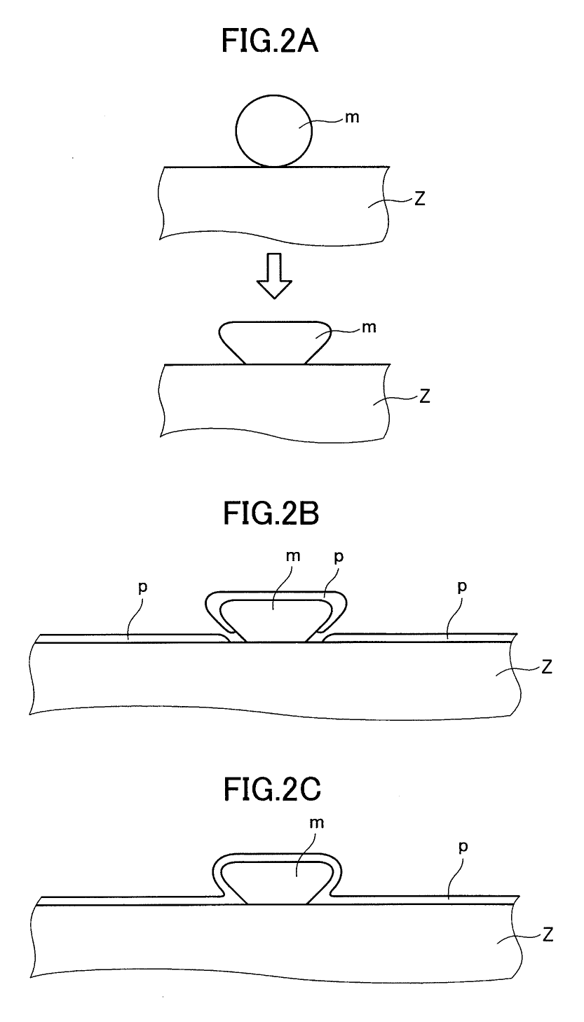

FIG. 2A is a schematic representation of what the present inventors found about the effect of depression by the guide roller 40 or other members that contact the surface of the substrate Z; as shown, a foreign object m adhering to the substrate's surface is depressed to deform into an inverse tapered shape having oblique sides that hang over the substrate Z, and this causes a significant drop in gas barrier quality.

To be more specific, if the substrate Z to which the foreign object m adheres in the state described above is processed by plasma-enhanced CVD with a view to depositing a gas barrier layer p, film deposition sometimes fails to reach the inversely tapered areas of the foreign object m. As a result, the deposited gas barrier layer p is by no means appropriate, as exemplified by the case where the coverage of the substrate Z and the foreign object m by the gas barrier layer p is incomplete (they are only partly covered) as schematically shown in FIG. 2B, or the case where the thickness of the gas barrier film p is inadequate, or the case where the gas barrier layer p is adequately thick but not adequately dense (its density is low). In other words, the foreign object m cannot be adequately covered with an appropriate gas barrier layer in the inversely tapered areas.

A further problem with the inappropriate areas of the gas barrier layer p that result from the inverse taper of the foreign object m is that the gas barrier layer p will readily break if it is subject to an external force, as in the case where it is depressed by the guide roller 42 positioned downstream of the drum 36.

With such incompletely covered areas or broken areas, the result is quite the same as what would occur in the entire absence of the gas barrier layer p. In addition, those areas of the gas barrier layer p which are not broken but are inadequately thick or those areas which are adequately thick but not adequately dense are incapable of providing the desired gas barrier quality. Therefore, those gas barrier films which are incompletely covered by a gas barrier layer or which have a broken gas barrier layer or which are covered with a gas barrier layer having any other inappropriate areas exhibit a very low gas barrier quality that is far from the desired level.

This drop in gas barrier quality becomes particularly noticeable if at least three foreign objects having a maximum length of 100 nm or more adhere per square centimeter of the substrate Z.

According to the study of the present inventors, this tendency is noticeable if the pressure exerted on the surface of the substrate Z before film deposition becomes 50 N/m² or more (if the surface of the substrate Z before film deposition has ever received a pressure of 50 N/m² or more). The tendency is even more noticeable if the pressure exerted on the surface of the substrate Z before film deposition becomes 80 N/m² or above. Depending on the diameter of rollers and other members that will contact the substrate Z, the tension to be exerted on the substrate Z to realize consistent transport is preferably at least 15 N/m for practical purposes but in this case, the pressure exerted on the substrate Z by the guide roller 40 and other contact members is more likely to become 50 N/m² or above.

On the other hand, the substrate Z can be transported in a very consistent manner if the pressure exerted on the substrate Z by the guide roller 40 and other contact members is 50 N/m² or above. Similarly, the substrate Z can be transported in a very consistent manner if a tension of at least 15 N/m is exerted on the substrate Z. Allowing the substrate Z to be transported consistently is advantageous for such purposes as improving productivity through, for example, increasing the transport speed of the substrate.

The present inventors further made intensive studies with a view to avoiding those inconveniences. As a result, the present inventors found that by depositing a gas barrier layer through plasma-enhanced CVD with a pressure of 60 Pa and above being applied during film deposition, the possible drop in gas barrier quality could be suppressed even when foreign objects adhering to the surface of the substrate Z were depressed before deposition of a gas barrier layer to assume an inverse tapered shape.

To be more specific, by ensuring that a gas barrier layer is deposited by plasma-enhanced CVD at a pressure of 60 Pa and above, film deposition can be performed in such a way that it will reach the inversely tapered areas of the foreign object m that may occur if the substrate Z receives a pressure of 50 N/m² and above. Thus, as shown schematically in FIG. 2C, one is able to deposit a gas barrier layer p that effectively covers the entire surface of the substrate Z and the foreign object m and which is appropriate in such aspects as thickness and denseness. In other words, by adjusting the gas barrier layer depositing pressure to be 60 Pa and above, an appropriate gas barrier layer p can be deposited to provide a very high coverage.

Thus, according to the present invention, not only is it possible for one to eliminate any areas that are substantially the same as what would occur in the entire absence of the gas barrier layer p but, at the same time, the deposited gas barrier layer can be prevented from breaking that would otherwise occur if it is pressed by the guide roller 42 and the like that are positioned downstream of the drum 36. In addition, one will be able to suppress deterioration in gas barrier quality that would otherwise occur if the deposited gas barrier layer had such defects as inadequate thickness and low denseness. Thus, in accordance with the present invention, gas barrier films having the desired gas barrier quality that will be afforded by the deposited gas barrier layer can be produced in a consistent manner.

The reason why adjusting the film depositing pressure in plasma-enhanced CVD to 60 Pa and above enables a gas barrier layer to be formed in such a way that it effectively reaches the inversely tapered areas of foreign objects is not clear. However, according to the study of the present inventors, when the film depositing pressure is set at 60 Pa and above, so many particles of gases such as reaction gases occur in the film deposition space (in the illustrated case, the gap between each of the showerhead electrodes and the substrate Z (or the drum 36 that carries it)) that those gas particles collide with one another or otherwise interact to fly about in various directions. As a result, the ions of the reaction gases (the excited reaction gases) also get under the inversely tapered areas of foreign objects, whereupon a gas barrier layer is deposited with an improvement in its ability to reach the inversely tapered areas of the foreign objects.

As a further finding of the study made by the present inventors, the ability of the gas barrier layer to reach the inversely tapered areas of the foreign objects (i.e., the coverage improving effect), namely, the ability to suppress the possible drop in gas barrier quality on account of the inversely tapered foreign objects can be exhibited more effectively by adjusting the pressure of film deposition through plasma-enhanced CVD to at least 100 Pa, especially to at least 150 Pa.

Note that the upper limit of the pressure of film deposition by plasma-enhanced CVD is not particularly limited and a suitable pressure (subatmospheric pressure) may be set as appropriate for the gas barrier layer to be deposited, the reaction gases to be used, the desired deposition rate, and the like; however, according to the study of the present inventors, the upper limit of the pressure of interest is preferably set at 5000 Pa or below, more preferably at 1000 Pa or below.

If the film deposition pressure exceeds 5000 Pa, too many particles of the reaction gases occur that particulate matter is more likely to be generated in the reaction atmosphere, giving rise to a greater possibility for side effects to occur that may cause adverse effects, such as inadequate closure of the inversely tapered areas of foreign objects that need be covered (i.e., the reaction gases that are to form a dense layer fail to reach the inverse tapers), and the formation of a gas barrier layer that is easy to break. In other words, by setting the film depositing pressure at 5000 Pa and below, the ability to deposit a gas barrier layer that will reach the inversely tapered areas of foreign objects can be secured more effectively.

Setting the film depositing pressure at 5000 Pa and below offers another advantage, i.e., enabling use of gases that are not recommended at atmospheric pressure for safety and other reasons.

In the process of the present invention for producing gas barrier films, the gas barrier layer to be deposited on the substrate Z is not particularly limited and among the gas barrier layers that may be employed include those made of silicon compounds such as silicon oxide, silicon nitride, silicon oxynitride, silicon oxynitrocarbide, those made of aluminum oxide, and any other known gas barrier layers that can be deposited by plasma-enhanced CVD.

Among these, a gas barrier layer that contains silicon as well as at least 3 atom. % of either one of oxygen, nitrogen and carbon is particularly advantageous for such reasons as the ability to attain high gas barrier quality and the ability to reduce the thickness of gas barrier layer at which the desired gas barrier quality is obtained.

Note also that in the process of the present invention for producing gas barrier films, the reaction gases used to deposit the gas barrier layer are not particularly limited and all known reaction gases may be used, depending upon the gas barrier layer to be deposited. If a silicon nitride layer is to be formed as a gas barrier layer, both silane gas and ammonia gas and/or nitrogen gas may be used as reaction gases; if a silicon oxide layer is to be formed, both silane gas and oxygen gas may be used as reaction gases. If desired, organosilane gases such as TEOS (tetraethoxysilane), HMDSO (hexamethyldisiloxane) and HMDSN (hexamethyldisilazane) may be employed.

Note that in the present invention, the reaction gases may, if necessarily, be used in combination with various other gases such as inert gases including helium gas, neon gas, argon gas, krypton gas, xenon gas and radon gas.

In the process of the present invention for producing gas barrier films, the conditions for depositing the gas barrier layer are not particularly limited, except for setting the film depositing pressure to 60 Pa and above. Hence, the conditions for depositing (forming) the gas barrier layer such as the flow rates of the reaction gases, the relative flow rates of the reaction gases, the intensity of plasma excitation power, the frequency of plasma excitation power, the temperature for film deposition (the substrate's temperature) and the deposition rate may be the same as those for the deposition of ordinary gas barrier layers.

Thus, the conditions for forming the gas barrier layer may be set as appropriate for the types of the gas barrier layer to be formed and the reaction gases used, the required deposition rate, the desired thickness of gas barrier layer, and the desired gas barrier quality.

Also note here that if, in the production process of the present invention, a gas barrier layer is to be deposited by CCP-enhanced CVD as in the illustrated case, the potential drop (V_{dc}) across the sheath adjacent the electrode closer to the substrate is preferably adjusted to 100 V or above. Thus, in the illustrated case, a gas barrier layer is preferably deposited with a bias potential of −100 V and below being applied to the drum 32 by means of the bias power supply 52.

By depositing a gas barrier layer through plasma-enhanced CVD with such bias potential being applied, the ions of reaction gases can be attracted toward the substrate Z, with higher efficiency in improving the entrance of the ions of reaction gases to get into the aforementioned inversely tapered areas of foreign objects and the ability of those ions to sputter the surface of the gas barrier layer being deposited. As a result, the ability of the gas barrier layer to reach the inversely tapered areas of foreign objects (its coverage) can be further improved and a gas barrier layer that is sufficiently dense and thick to effectively cover the substrate and foreign objects can be deposited in a more advantageous way, and a possible drop in gas barrier quality that is due to the inversely tapered areas of foreign objects can be suppressed.

It should also be noted that if, in the production process of the present invention, a gas barrier layer is to be deposited by CCP-enhanced CVD as in the illustrated case, the electrode-to-electrode distance is preferably set at 10-50 mm. Namely, in the illustrated case, the distance between each of the showerhead electrodes 38a-38d and the drum 36 is preferably set at 10-50 mm.

In the case of depositing a gas barrier layer at a fast speed that corresponds to deposition at a stationary rate (deposition rate with the substrate Z held still) of several hundred nanometers per minute, an electrode-to-electrode distance greater than 50 mm will increase the chance of particulate matter to occur, thus allowing a greater amount of foreign objects to adhere to the substrate Z. This phenomenon is generally more likely to occur at increasing pressure and in the present invention, the electrode-to-electrode distance is advantageously 50 mm or less. On the other hand, if the electrode-to-electrode distance is less than 10 mm, inconveniences sometimes occur, as exemplified by deteriorated uniformity in the distribution of the thickness and quality of gas barrier layer and increased abnormal electric discharge.

Therefore, by adjusting the electrode-to-electrode distance to lie within the range specified above, the amount of foreign objects that will adhere to the substrate Z can be reduced so that a gas barrier layer that is sufficiently dense and thick to effectively cover the substrate and foreign objects can be deposited in a more advantageous way, and a possible drop in gas barrier quality due to the inversely tapered areas of foreign objects can be suppressed.

The gas barrier film, or the substrate Z on which the gas barrier layer has been deposited as it passes through the regions that are in a face-to-face relation with the showerhead electrodes 38a-38d while it is supported and transported by the drum 36, is guided by the guide roller 42 into the specified path such that it is transported into the takeup compartment 16 via the slit 56a formed in the partition 56 that separates the film deposition compartment 14 and the takeup compartment 16.

In the illustrated case, the takeup compartment 16 has a guide roller 58, a takeup shaft 30, and an evacuating means 60.

The substrate Z (gas barrier film) transported into the takeup compartment 16 is guided by the guide roller 58 onto the takeup shaft 30, about which it is rolled to produce a gas barrier film roll that is subjected to the next step.

Like the aforementioned supply compartment 12, the takeup compartment 16 is also provided with an evacuating means so that during film deposition, the pressure in the takeup compartment 16 is reduced to a degree of vacuum that matches the pressure at which the gas barrier layer was deposited in the film deposition compartment 14.

While the process of the present invention for producing gas barrier films has been described above in detail, the present invention is by no means limited to the foregoing embodiment and it should be understood that various improvements and modifications can of course be made without departing from the gist of the present invention.

Here, specific examples of the present invention are given in order to describe it in greater detail.

### EXAMPLE 1

Using a production apparatus generally indicated by 10 in FIG. 1, a silicon nitride layer of 50 nm thick was deposited as a gas barrier layer on a surface of a substrate Z to prepare a gas barrier film.

The substrate Z was a polyester film with a thickness of 188 μm (LUMINICE, a polyethylene terephthalate film manufactured by TORAY ADVANCED FILM CO., LTD.) The guide rollers 26 and 40 were designed to be of the same diameter and the tension of the substrate Z being transported was so adjusted that each of these guide rollers would exert a pressure of 50 N/m² on the substrate Z. Note that the tension of the substrate Z was 16.1 N/m.

Silane gas, ammonia gas and nitrogen gas were used as reaction gases. The silane gas was flowed at a rate of 200 sccm, the ammonia gas at 300 sccm, and the nitrogen gas at 2500 sccm. These flow rates were for the reaction gases that were supplied to each of the four showerhead electrodes 38a-38d.

The intensity and frequency of plasma excitation power were set at 1.5 kW and 13.56 MHz, respectively, for each of the four showerhead electrodes 38a-38d. The electrode-to-electrode distance (the average distance between each showerhead electrode and the drum 36) was set at 20 mm.

The film deposition rate was set at 200 nm/min for the stationary mode.

Under those conditions, gas barrier layers were deposited with the deposition pressure being varied at five levels of 40 Pa, 60 Pa, 80 Pa, 100 Pa, and 150 Pa.

Each of the gas barrier films obtained at these deposition pressures was sampled at four points that were 5 meters apart in the longitudinal direction, and each sample was measured for water-vapor transmission rate (WVTR [g/(m²·day)]) by the MOCON method. Note that those samples which exceeded the limit for measurement of WVTR by the MOCON method were measured for WVTR by the calcium corrosion method (see the official gazette of JP 2005-283561 A).

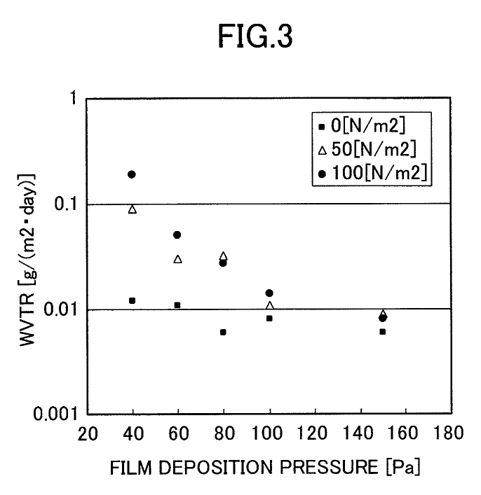

For each of the gas barrier films that were prepared at the respective film deposition pressures, the average of four WVTR values is shown in Table 1 below and FIG. 3.

### EXAMPLE 2

Gas barrier films were prepared and measured for WVTR [g/(m²·day)] as in Example 1, except that the pressure to be exerted on the substrate Z by the guide rollers 26 and 40 was changed to 100 N/m² (the tension of the substrate Z was 32.2 N/m).

The data for the average of four WVTR values are shown for each sample in Table 1 below and FIG. 3.

### EXAMPLE 3

Gas barrier films were prepared and measured for WVTR [g/(m²·day)] as in Example 1, except that the guide rollers 26 and 40 were step-profile rollers each having a larger-diameter portion at both ends (in a direction crossing the transport direction at right angles) that was the only site at which the roller would contact and guide the substrate Z. Thus, in Example 3, prior to gas barrier layer deposition, neither of the guide rollers 26 and 40 contacted the center region of the substrate Z in the direction of its width and, hence, the substrate Z received a pressure of 0 N/m².

WVTR [g/(m²·day)] measurement was conducted as in Example 1, provided that sampling was done in that region of the substrate Z which received no area pressure from the guide rollers 26 and 40 (i.e., the region receiving a pressure of 0 N/m²) prior to gas barrier layer deposition.

The data for the average of four WVTR values are shown for each sample in Table 1 below and FIG. 3.

### EXAMPLE 4

Gas barrier films were prepared and measured for WVTR [g/(m²·day)] as in Example 1, except that the pressure to be exerted on the substrate Z by the guide rollers 26 and 40 was changed to 1000 N/m².

The data for the average of four WVTR values are shown for each sample in Table 1 below.

TABLE 1

| Area | | | | | |
|---|---|---|---|---|---|
| pressure | Film deposition pressure [Pa] | | | | |
| [N/m²] | 40 | 60 | 80 | 100 | 150 |
| 0 | 1.2E-02 | 1.1E-02 | 6.0E-03 | 8.0E-03 | 6.0E-03 |
| 50 | 8.9E-02 | 3.0E-02 | 3.2E-02 | 1.1E-02 | 9.0E-03 |
| 100 | 1.9E-01 | 5.1E-02 | 2.7E-02 | 1.4E-02 | 8.0E-03 |
| 1000 | 4.9E-01 | 1.1E-01 | 1.1E-01 | 7.6E-02 | 5.2E-02 |

As is clear from Table 1 and FIG. 3, when the substrate Z received no area pressure (0 N/m²) prior to gas barrier layer deposition, there was no substantial variation in WVTR despite the variation in the film deposition pressure; in other words, there occurred no drop in gas barrier quality on account of foreign objects adhering to the surface of the substrate Z.

In contrast, when the substrate Z received pressures of 50 N/m² and above prior to gas barrier layer deposition, the gas barrier layers that were deposited at a pressure of 40 Pa broke on account of inversely tapered foreign objects and failed to provide satisfactory gas barrier quality. However, according to the present invention in which the substrate Z received pressures of 50 N/m² and above prior to gas barrier layer deposition at pressures of 60 Pa and above, the deposited gas barrier layers effectively covered the inversely tapered foreign objects to suppress a possible drop in gas barrier quality that would otherwise occur if the gas barrier layers should break. In particular, by setting the film deposition pressure at 100 Pa and above, one could secure gas barrier quality of substantially comparable levels to the case where the substrate Z received no area pressure at all. As is clear from Table 1, even when the substrate Z received pressures of 1000 N/m² prior to gas barrier layer deposition, satisfactory gas barrier quality can be obtained.

What is claimed is:

1. A process for producing gas barrier films comprising the steps of:
applying a pressure of 50 N/m² and above to a surface of a substrate; and
subsequently forming a gas barrier layer on the surface of the substrate by plasma-enhanced CVD in a pressure atmosphere of 60 Pa and above.

2. The process according to claim 1, wherein the substrate is an elongated base film wound around a substrate roll, from which the substrate is unwound and transported in a specified path as its surface is subjected to a pressure of 50 N/m² and above with a guide roller, the substrate thereafter entering a film deposition compartment with a pressure atmosphere of 60 Pa and above so that the gas barrier layer is formed on the surface of the substrate.

3. The process according to claim 1, wherein the plasma-enhanced CVD is capacity coupled plasma enhanced CVD using a pair of electrodes, with the electrode-to-electrode distance being 10-50 mm.

4. The process according to claim 1, wherein the plasma-enhanced CVD is capacity coupled plasma enhanced CVD using a pair of electrodes, the substrate being in contact with one of the pair of electrodes, said one electrode being such that the potential drop across the sheath adjacent thereto is 100 V and above.

5. The process according to claim 1, wherein the pressure is applied to the surface of the substrate is 1000 N/m² and below.

6. The process according to claim 1, wherein the gas barrier layer is formed in a pressure atmosphere of 5000 Pa and below.
